(19) United States
(12) Patent Application Publication
(10) Pub. No.: US 2010/0210060 A1
(43) Pub. Date: Aug. 19, 2010

(54) DOUBLE ANNEAL PROCESS FOR AN IMPROVED RAPID THERMAL OXIDE PASSIVATED SOLAR CELL

(76) Inventors: Peter Borden, San Mateo, CA (US); Li Xu, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/371,090

(22) Filed: Feb. 13, 2009

(51) Int. Cl. H01L 31/18

(52) U.S. Cl. 438/61; 257/E31.001

(57) ABSTRACT

Embodiments of the invention generally contemplate methods for treating a semiconductor solar cell substrate to reduce the number of undesirable material defects or interface state traps on the surface or within the substrate. These defects can adversely affect the efficiency of the solar cell because electron-hole pairs tend to recombine with the defects and are essentially lost without generating any useful electrical current. In one aspect, a method of forming a solar cell on a semiconductor substrate is provided, comprising doping a front surface of the substrate, applying a passivating layer to the front surface and/or a back surface of the substrate, and annealing the substrate to reduce the interface state trap density (Dᵢₜ).

### BACKGROUND OF THE INVENTION

1. Field of the Invention

Embodiments of the present invention generally relate to photovoltaic/solar cell and solar panel manufacturing.

2. Description of the Related Art

Photovoltaics (PV) systems can generate power for many uses, such as remote terrestrial applications, battery charging for navigational aids, telecommunication equipments, and consumer electronic devices, such as calculators, watches, radios, etc. One example of PV systems includes a stand-alone system which generates power for direct use or with local storage. Another type of PV system is connected to conventional utility grid with the appropriate power conversion equipment to produce alternating current (AC) compatible with any conventional utility grid.

PV or solar cells are material junction devices which convert sunlight into direct current (DC) electrical power. When exposed to sunlight (consisting of energy from photons), the electric field of solar cell p-n junctions separates pairs of free electrons and holes, thus generating a photo-voltage. A circuit from n-side to p-side allows the flow of electrons when the solar cell is connected to an electrical load, while the area and other parameters of the PV cell junction device determine the available current. Electrical power is the product of the voltage times the current generated as the electrons and holes recombine.

Currently, solar cells and PV panels are manufactured by starting with many small silicon sheets or wafers as material units and processing them into individual photovoltaic cells before they are assembled into PV modules and solar panels. These silicon sheets are generally saw-cut p-type boron doped silicon sheets less than about 0.3 mm thick, precut to the sizes and dimensions that will be used, e.g., 100 mm×100 mm, or 156 mm×156 mm. The cutting (sawing) or ribbon formation operation on the silicon sheets damages the surfaces of the precut silicon sheets to some degree, and etching processes using, for example, alkaline or acid etching solutions are performed on both surfaces of the silicon sheets to remove about 10 μm to 20 μm of material from each surface and provide textures thereon.

Junctions are then formed by diffusing an n-type dopant onto the precut p-type silicon sheets, generally performed by phosphorus diffusion as phosphorus is widely used as the n-type dopant for silicon in solar cells. One phosphorus diffusion process includes coating phosphosilicate glass compounds onto the surface of the silicon sheets and performing diffusion/annealing inside a furnace. Another example of diffusing a phosphorus dopant into silicon includes bubbling nitrogen gas through liquid phosphorus oxychloride (POCl₃) sources which are injected into an enclosed quartz furnace loaded with batch-type quartz boats containing the silicon sheets. Typically, a high temperature between about 850° C. and about 1,050° C. is needed to form and create a p-n junction depth of about 0.1 μm up to about 0.5 μm.

Following dopant diffusion, a phosphorus-doped SiO₂ layer formed during the diffusion is generally removed with a wet etch. One or both surfaces of a PV cell can also be coated with suitable dielectrics after the p-n junction is formed. Dielectric layers are used to minimize surface charge carrier recombination and some dielectric materials, such as silicon dioxide, titanium dioxide, or silicon nitride, can be provided as antireflective coating to reduce reflection losses of photons.

The front or sun facing side of the PV cell is then covered with an area-minimized metallic contact grid for transporting current and minimizing current losses due to resistance through silicon-containing layers. Some blockage of sunlight or photons by the contact grid is unavoidable but can be minimized. The bottom of the PV cell is generally covered with a back metal which provides contact for good conduction as well as high reflectivity. Metal grids with patterns of conductive metal lines are used to collect current. Generally, screening printing thick-film technology is used in the PV cell industry to layer a conductive paste of metal materials, e.g., silver, etc., into a desired pattern and deposit a metal material layer to the surface of the silicon sheets or substrates for forming metal contact fingers or wiring channels on the front and/or back side of the solar cell. Other thin film technologies may be used for contact formation or electrode processing. The deposited metal layer, formed into contacts, is often dried and then fired or sintered at high temperature to form into good conductors in direct contact with underlying silicon materials, and a single PV cell is made. Generally, both silver and aluminum are contained in the screen printing paste for forming back side contacts with good contact conductor to silicon material and easy soldering.

Manufacturing high efficiency solar cells at low cost (providing low unit cost per Watt) is the key to making solar cells more competitive in the generation of electricity for mass consumption. Even small improvements in cost per Watt substantially increase the size of the available market. The efficiency of solar cells is directly related to the ability of a cell to collect charges generated from absorbed photons in the various layers. When electrons and holes re-combine, the incident solar energy is re-emitted as heat or light. Therefore, there is a need for a low cost solar cell formation process that creates solar cells that have an improved efficiency.

### SUMMARY OF THE INVENTION

The present invention generally provides a method for processing a solar cell substrate, comprising forming a passivating layer over a surface of the solar cell substrate in a first processing chamber, wherein at least a portion of the passivating layer is formed a temperature greater than 800° C., and then heating the solar cell substrate to a temperature greater than 800° C. to reduce the number of interface state traps on the surface of or within the solar cell substrate.

The present invention also provides a method for processing a solar cell substrate, comprising forming a passivating layer over a surface of the solar cell substrate in a first processing chamber, wherein at least a portion of the passivating layer is formed at a temperature greater than 850° C., transferring the solar cell substrate to a second processing chamber, wherein the temperature of the solar cell substrate during the process of transferring is less than about 850° C., and then heating the solar cell substrate to a temperature greater than 850° C to reduce the number of interface state traps on the surface of or within the solar cell substrate.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process flow diagram summarizing a double anneal process for a semiconductor solar cell substrate according to one embodiment of the invention.

FIGS. 2A-2D are schematic side views of the semiconductor solar cell substrate at various stages of the double anneal process of FIG. 1 according to one embodiment of the invention.

FIG. 3 illustrates the degree of reduction in the density of material defects, or interface state traps, in the semiconductor solar cell substrate as a result of the double anneal process of FIG. 1 according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally contemplate methods for treating a semiconductor solar cell substrate to reduce the number of undesirable material defects, or interface state traps, on the surface or within the substrate. These defects can adversely affect the efficiency of the solar cell because electron-hole pairs tend to recombine with the defects and are essentially lost without generating any useful electrical current. In one aspect, a method of forming a solar cell on a semiconductor substrate is provided, comprising doping a front surface of the substrate, applying a passivating layer to the front surface and/or a back surface of the substrate, and then in a subsequent anneal process the substrate is heated to a desired temperature to reduce the interface state trap density (Dᵢₜ).

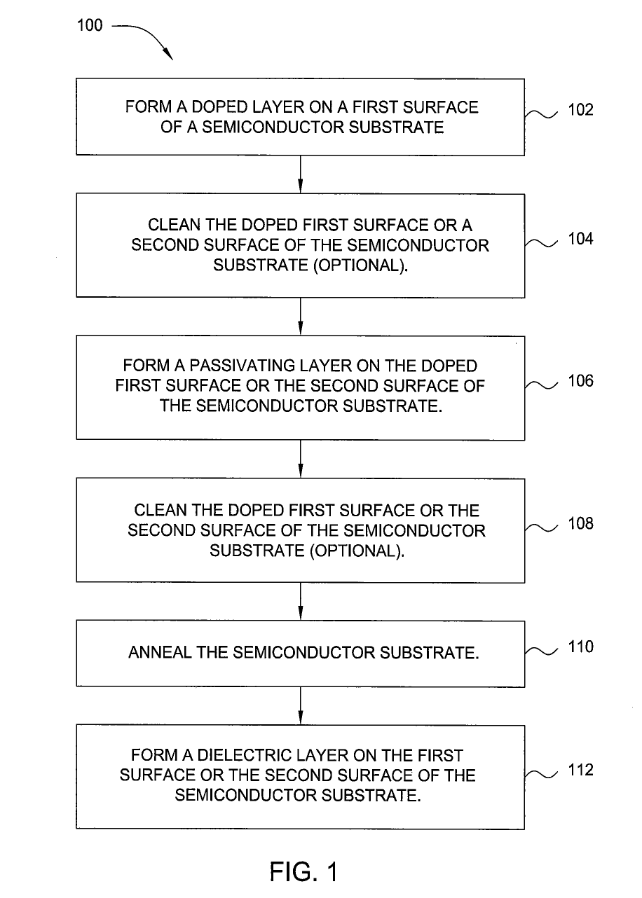

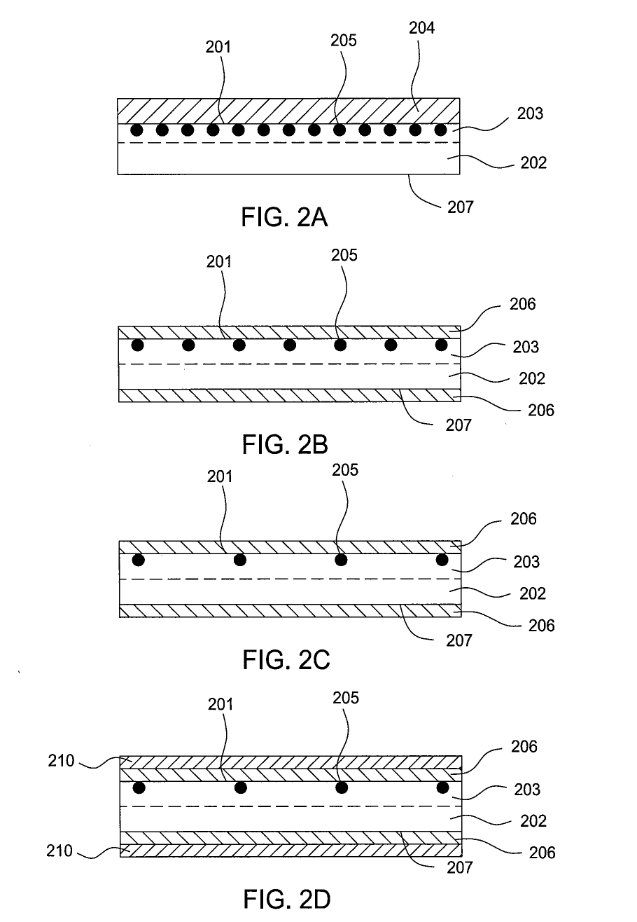

FIG. 1 is a process flow diagram summarizing a method 100 according to one embodiment of the invention. FIGS. 2A-2D are schematic side views of a semiconductor solar cell substrate at various stages of the process illustrated in FIG. 1. At step 102, as shown in FIGS. 1 and 2A, a doped layer 203 is formed on a front surface 201 of a semiconductor solar cell substrate 202. The doped layer 203 may be formed by any process known to the art, such as a furnace type diffusion process, implant process, or other similar process as described above. In one embodiment, the front surface 201 of the substrate 202, which may contain silicon, is coated with a dopant material 204 that may comprise an n-type dopant such as phosphorous (P). In another embodiment, however, other n-type or p-type dopant materials may be used, which may comprise boron (B) or arsenic (As). During step 102, the dopant material 204 diffuses into the front surface 201 of the substrate 202 to form the doped layer 203 with a sharply declining dopant concentration at the interface between the substrate 202 and the dopant material 204. The doped layer 203 may be between about 100 nm and about 1000 nm thick, and in one embodiment is about 200 nm thick. In one embodiment, after dopant diffusion is completed, the dopant material 204 is stripped from the front surface 201 of the substrate 202. In one embodiment, the dopant concentration is between about 10¹⁹ atoms/cm³ and about 10²¹ atoms/cm³ at the front surface 201 of the substrate 202 and sharply falls below about 10¹⁷ atoms/cm³ at a depth of about 0.2 μm. In one example, the decay rate of concentration in such doped layers may be as high as 50 nm per decade of concentration (nm/dec).

When a high concentration of dopant remains at the front surface 201 of the substrate 202, it may adversely affect the effectiveness of a passivating layer applied to the substrate 202. One purpose of the passivating layer is to reduce recombination of electron-hole pairs with material defects on the surface or within the substrate 202. Material defects 205, or interface state traps, including unfulfilled dangling bonds of the substrate material, that can adversely affect operation of a solar cell device because electron-hole pairs recombine with the unfulfilled dangling bonds and are essentially lost without generating any useful electrical current. In one embodiment, a silicon substrate is coated with a passivating silicon oxide layer such that the deposited or grown silicon oxide material ties up some of the dangling bonds on the surface of the silicon substrate.

A parameter that is typically used in the industry to indicate the degree to which a surface or body is characterized by material defects is the “interface state trap density,” or “Dᵢₜ.” “Interface state trap density,” or “Dᵢₜ,” is utilized to essentially measure the number of material defects per unit of area. Another variable used in the industry is the “recombination velocity,” or “S,” which is a measure of the rate at which electron-hole pairs recombine at the material defects at or near the surface. The recombination velocity S is mathematically proportional to the interface state trap density Dᵢₜ. The lower the interface state trap density Dᵢₜ and/or the recombination velocity S of a material, the less defects in the material.

Prior to depositing a passivating layer 206, at step 104, as shown in FIG. 1, the front surface 201 and/or the back surface 207 of the substrate 202 may optionally be cleaned to remove any contamination or other defects. The clean process may comprise a treatment using any of the widely known wet clean reagents, such as various solutions containing HF, water, peroxide, alcohol, organic acids, and/or the like. In one embodiment, the substrate is exposed to a dilute (50:1) H₂O:HF solution to remove a thin surface layer of silicon dioxide. In another embodiment, the well known RCA clean process is used.

At step 106, as shown in FIGS. 1 and 2B, a passivating layer 206 is formed on the front surface 201 and/or the back surface 207 of the substrate. The passivating layer 206 is from about 20 Å to about 150 Å thick, such as between about 40 Å to about 100 Å thick. In one example, passivating layer 206 is about 50 Å thick. In one embodiment, the passivating layer 206 may be an oxide or nitride layer, and is preferably formed in a dopant-free, high-temperature process that additionally results in diffusion of the dopant atoms found in the previously deposited dopant material 204 being driven deeper into the substrate 202. In one embodiment, the passivating layer 206 is a silicon oxide (SiOₓ) or silicon nitride (SiₓN_{y}) layer that is dopant-free. In one embodiment, the passivating layer 206 may be formed on a silicon substrate during a rapid thermal oxidation process. In another embodiment, the surfaces of a silicon substrate are exposed to an oxygen-containing plasma or to a nitrogen-containing plasma. In still another embodiment, the surfaces of a silicon substrate are exposed to nitrogen or to a nitrogen-containing gas, such as ammonia.

When forming the passivating layer 206 using a rapid thermal oxidation process, the substrate 202 is exposed to an oxygen-containing gas at a high temperature. The substrate 202 is disposed in a thermal treatment chamber, and a gas mixture is provided to the chamber. The gas mixture usually comprises oxygen, and may comprise other gases such as hydrogen or water vapor. The gas may additionally be ionized to any convenient degree. During processing the substrate 202 is rapidly heated in the presence of the gas mixture to a target temperature between about 800° C. and about 1,200° C. for between about 9 sec and about 120 sec at a pressure of between about 100 mTorr and about 10 Torr, such as about 850 mTorr. In one embodiment, the substrate is heated at a rate between about 200° C./sec and about 400° C./sec. Such heating rates may be achieved by use of a heated support or by use of radiant energy sources such as heat lamps. The RadOx™ process available from Applied Materials, Inc., of Santa Clara, Calif., may be used to form the passivating layer 206 in a way that also causes the dopant material 204 to diffuse into the bulk of the substrate 202. In one embodiment using the RadOx process, the substrate may be beneficially treated in less than about 30 sec.

In one embodiment, the passivating layer 206 is applied only to the front surface 201 of the substrate 202, and a separate passivating layer is applied to the back surface 207 of the substrate 202. In another embodiment, the passivating layer 206 is applied to both surfaces 201 and 207 simultaneously. In one embodiment, the back surface 207 may be doped with a p-type dopant such as boron prior to passivation. Subjecting the substrate 202 to a high-temperature process modifies the concentration profile of dopants in the substrate 202. Prior to a high-temperature passivation layer deposition process (step 106), the dopant concentration may have a decay rate of between about 50 nm/dec and about 100 nm/dec, such as about 90 nm/dec. After the high-temperature treatment, the dopant concentration may have a decay rate of between about 100 nm/dec and about 300 nm/dec, such as about 200 nm/dec. In one embodiment, the high-temperature treatment is performed at a temperature selected to diffuse the dopant material 204 from the front surface 201 into the bulk of the substrate 202, producing a region of slow concentration decay near the front surface 201, and a region of fast concentration decay deeper in the substrate 202. The region of slow concentration decay may have a rate of concentration decay between about 0.5 μm/dec and about 1.0 μm/dec, such as about 0.8 μm/dec. The region of fast concentration decay may have a rate of concentration decay between about 50 nm/dec and about 100 nm/dec, such as about 70 nm/dec. In one embodiment, the region of slow concentration decay may have a thickness of between about 100 nm and about 300 nm, such as about 200 nm, and the region of fast concentration decay may have a thickness of between about 100 nm and about 300 nm, such as about 200 nm. Thus, the process of passivating the substrate 202 is performed so as to smooth the concentration profile of the dopant, generally reducing the rate of decay of concentration with depth. Smoothing the concentration profile this way aids in passivating the substrate 202 because it extends the doped layer 203 deeper into the substrate, as compared to the original layer in FIG. 2A, that can absorb holes and repel electrons from the bulk layers in the case of the doped layer 203 having an n-type dopant disposed therein and the substrate 202 having a p-type dopant disposed therein, or absorb electrons and repel holes in the case of the doped layer 203 having a p-type dopant disposed therein and the substrate 202 having an n-type dopant disposed therein. Smoothing the concentration profile also reduces the surface concentration of the dopant, reduces surface recombination, and makes passivation more effective. A high surface concentration would shield the lower doped region from the effect of the passivating layer 206. Moreover, the passivating layer 206, aided by the inherent high-temperature cycle during its formation, chemically bonds with and eliminates some of the material defects 205 found at the surface or within the substrate 202. This is illustrated by a lower number of material defects 205 in FIG. 2B compared to that in FIG. 2A.

Subjecting the substrate 202 to a high-temperature formation process during the passivating layer 206 formation process causes movement of dopant atoms into the substrate. It is generally desirable to perform initial diffusion (step 102) of dopant atoms to a depth shallower than the final desired depth. For example, a junction intended to have a dopant layer 0.3 μm thick may be subjected to initial diffusion to a depth of 0.3 μm, and the dopant diffused to a depth of 0.5 μm during the passivation process. This reduces the time required for the initial diffusion process.

At step 108, as shown in FIG. 1, the front surface 201 and/or the back surface 207 of the substrate 202 may optionally be cleaned to remove any residual contamination. The clean process may comprise a treatment using any of the widely known wet clean reagents, such as various solutions containing HF, water, peroxide, alcohol, acids, and/or the like.

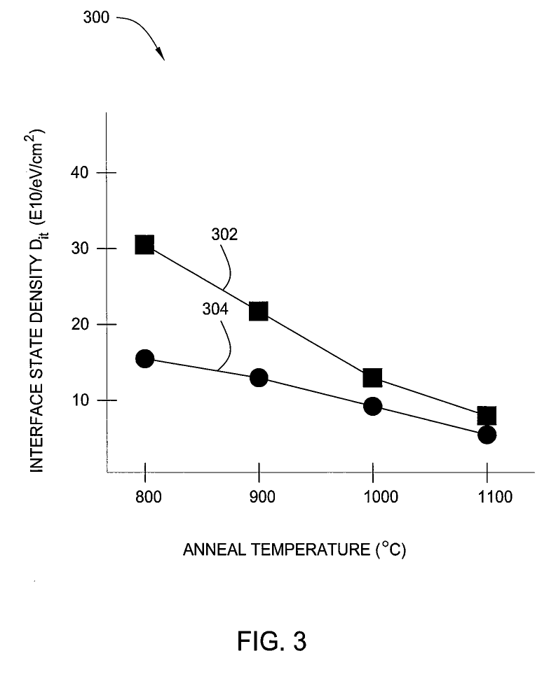

At step 110, as shown in FIGS. 1 and 2C, the substrate 202 is further heated, or annealed, in a thermal treatment chamber, such as a rapid thermal processing (RTP) chamber available from Applied Materials, Inc., of Santa Clara, Calif. This step is considered as a “second” anneal process because the previous passivation formation step was already performed at a high temperature. In one embodiment, the “second” anneal (step 110) is performed immediately on the substrate 202 following the passivating layer deposition (step 106) in the same processing chamber, and thus the optional clean (step 108) is skipped. In another embodiment, after the passivating layer deposition (step 106), the substrate 202 is cooled down, cleaned (step 108), and then annealed (step 110). While high-temperature processing steps are typically avoided in conventional solar cell fabrication processing sequences, since they generally contribute to uncontrolled dopant diffusion in the solar cell substrate, this second anneal step has surprisingly been found to further reduce the number of material defects 205 on the surface or within the substrate 202, and thus improve the solar cell efficiency. The experimental data 300 in FIG. 3 illustrate the degree of reduction in interface state trap density (Dᵢₜ) as a result of the second anneal after the formation of a silicon oxide passivating layer, both steps done in a rapid thermal processing system. In the experiment that produces the data in FIG. 3, the front and back surfaces of the substrate are coated with rapid thermal oxide to measure the passivation effect. The back surface of the substrate is first cleaned with a HF-last process to remove residual oxide. Then a RadOx oxide (oxygen+hydrogen, on the order of 70 Å thick, 900° C., 30 seconds) is grown on the back surface. The substrate is removed from the system, followed by a second clean, which removes about 20 Å from the oxide on the back surface. Then an oxide about 50 Å thick is grown on the front surface of the substrate. During this growth the oxide on the back surface receives an anneal equal to the growth conditions of 900° C., 30 seconds. Curve 302 illustrates the level of Dᵢₜ not having the second anneal (i.e. the oxide on the front surface of the substrate). Curve 304 illustrates the level of Dᵢₜ having the second anneal (i.e. the oxide on the back surface of the substrate). The x-axis indicates the temperature of the substrate during the passivation process and the second anneal process. According to the experimental data, the higher the temperature of the passivation process, the more material defects can be eliminated initially, and the less of a difference the second anneal will make in further eliminating the material defects. In one embodiment, the second anneal is carried out in a temperature range from about 800° C. to about 1100° C. for a duration from about 2 sec to about 120 sec.

At step 112, as shown in FIGS. 1 and 2D, a dielectric layer 210 is formed over the surfaces 201 and 207 of the substrate 202. The dielectric layer 210 may comprise oxygen, nitrogen, hydrogen, carbon, or combinations thereof, depending on the needs of particular embodiments. In one embodiment, a nitride layer with an index of about 2.07 and a thickness of about 70 nm may be formed over the two surfaces. The dielectric layer 210 may further passivate the surfaces of the substrate, and may also serve as an anti-reflective coating to prevent loss of incident radiation by reflection. In one embodiment, the dielectric layer may be formed over only one surface of the substrate, leaving the opposite surface exposed. The dielectric layer 210 may be formed by any convenient process, such as chemical vapor deposition, which may be plasma-enhanced, physical vapor deposition, atomic layer deposition, and the like. The dielectric layer 210 may have a dielectric constant of about 6 or less, such as between about 1.48 and 6. In one embodiment, the dielectric layer may have a dielectric constant of between about 4 and about 6. In one embodiment, the dielectric layer may have a dielectric constant of between about 1.48 and about 4. In one embodiment, the dielectric layer 210 is formed by either a plasma-enhanced chemical vapor deposition process, where silane is broken down in the presence of ammonia (NH₃), or a reactive sputtering process, where silicon is sputtered in the presence of ammonia. N₂O or N₂ can also be used as a source of nitrogen, although the hydrogen in ammonia is preferred as it provides better passivation of broken silicon bonds. Process temperature is typically between 300° C. and 400° C.

It should be noted that use of a thermal process to form a passivating layer, as described above, improves the performance of all passivating layers in the structure. The high surface dopant concentration of prior art solar cells, the high charge content thereof, and the high level of material defects reduce the passivating effect of a nitride layer by masking the inherent charge content of the nitride layer. When the inherent charge content of the nitride layer is masked, the free electrons in the bulk layer may drift closer to the doped layer and may recombine with holes migrating toward the doped layer. Smoothing and deepening the concentration profile of the dopant, as well as reducing the number of material defects on the surface or within the substrate, reduces recombination of charge carriers by repelling electrons toward the undoped surface and by improving the electron-repelling effect of the passivating layer. Use of such a process may obviate the need for doping two surfaces of the solar cell substrate in some embodiments, allowing for solar cells with a single doped surface, with the opposite surface having a dielectric passivating layer.

While the foregoing is directed to embodiments of the invention, other and further embodiments of the invention may be devised without departing from the basic scope thereof, and the scope thereof is determined by the claims that follow.

What is claimed is:

1. A method of processing a solar cell substrate, comprising:
forming a passivating layer over a surface of the solar cell substrate in a first processing chamber, wherein at least a portion of the passivating layer is formed at a first temperature that is greater than 800° C.; and then
heating the solar cell substrate to a second temperature that is greater than 800° C.

2. The method of claim 1, wherein the first temperature is greater than about 850° C. and is adapted to decrease the number of interface state traps.

3. The method of claim 1, the second temperature is greater than about 850° C. and is adapted to decrease the number of interface state traps.

4. The method of claim 1, further comprising:
doping the surface of the solar cell substrate with a dopant atom; and
the forming the passivating layer further comprises forming a dielectric layer over the doped surface of the solar cell substrate.

5. The method of claim 1, wherein the passivating layer is formed by a rapid thermal oxidation process.

6. The method of claim 1, wherein the passivating layer comprises silicon and nitrogen.

7. The method of claim 1, wherein forming the passivating layer comprises forming an oxygen-containing film on the surface of the solar cell substrate, the film having a thickness between about 20 Angstroms and about 150 Angstroms.

8. The method of claim 4, wherein forming the passivating layer reduces the decay rate of the dopant concentration with depth into the substrate.

9. The method of claim 4, wherein forming the passivating layer reduces a concentration of the dopant atoms on the surface of the solar cell substrate by at least 10%.

10. The method of claim 4, wherein forming the passivating layer modifies the concentration profile of the dopant in the solar cell substrate from a decay rate of between about 50 nm/dec and about 100 nm/dec to a decay rate of between about 100 nm/dec to about 300 nm/dec.

11. The method of claim 4, wherein forming the passivating layer comprises:
disposing the solar cell substrate in a processing region of a processing chamber;
flowing an oxygen-containing gas mixture in the processing region; and
heating the solar cell substrate to a predetermined temperature selected to form an oxygen-containing film on the surface of the solar cell substrate and cause the dopant atoms to diffuse deeper into the solar cell substrate.

12. The method of claim 11, wherein the oxygen-containing film is a silicon oxide film.

13. The method of claim 11, wherein the oxygen-containing film has a thickness less than 100 Angstroms.

14. The method of claim 11, wherein heating the solar cell substrate to the predetermined temperature reduces a concentration of the dopant on the surface of the solar cell substrate by at least 10%.

15. A method of processing a solar cell substrate, comprising:
forming a passivating layer over a surface of the solar cell substrate in a first processing chamber, wherein at least a portion of the passivating layer is formed at a first temperature that is greater than about 850° C.;
transferring the solar cell substrate to a second processing chamber, wherein the temperature of the solar cell substrate during the process of transferring is less than about 850° C.; and then
heating the solar cell substrate to a second temperature that is greater than 850° C. to reduce the number of interface state traps on the surface of or within the solar cell substrate.

16. The method of claim 15, wherein the first temperature is greater than about 850° C. and is adapted to decrease the number of interface state traps.

17. The method of claim 15, the second temperature is greater than about 850° C. and is adapted to decrease the number of interface state traps.
